(19) United States
(12) Patent Application Publication
(10) Pub. No.: US 2025/0277839 A1
(43) Pub. Date: Sep. 4, 2025

(54) SYSTEM AND METHOD OF CALCULATING AND OPTIMIZING THE ENERGY CONSUMPTION OF COMPONENTS IN AN ELECTRIC VEHICLE

(71) Applicant: V-HOLA Labs Ltd., Kfar Saba (IL)

(72) Inventor: Asaf TSIN, Kfar Saba (IL)

(73) Assignee: V-HOLA Labs Ltd., Kfar Saba (IL)

(21) Appl. No.: 18/863,708

(22) PCT Filed: May 10, 2023
(86) PCT No.: PCT/IL2023/050487

§ 371 Date: Nov. 7, 2024

Related U.S. Application Data
(60) Provisional application No. 63/340,072, filed on May 10, 2022.

(51) Int. Cl. G01R 31/00; G01R 15/14; G01R 19/00

(52) U.S. Cl. CPC G01R 31/007; G01R 15/14; G01R 19/0092

(57) ABSTRACT

A system and a method of calculating the current consumption of components in a vehicle are disclosed. The system may include a controller and a memory stored thereon instructions for executing the method. The method comprising: receiving from at least one magnetic flux sensor located at a known location in the vehicle, a magnetic flux pattern at various frequencies, indicative of the magnetic field at the location; identifying at least one first magnetic flux maximum at a first frequency corresponding to a first component of the vehicle; and calculating a first current consumption of the first component based on the at least one first magnetic flux maximum.

### CROSS-REFERENCE TO RELATED APPLICATIONS

This application is an International Patent application that claims the benefit of priority of U.S. Provisional Patent Application No. 63/340,072, filed May 10, 2022, which is hereby incorporated by reference in their entirety.

### FIELD OF THE INVENTION

The present invention relates generally to a method of calculating the energy consumption of components of a vehicle. More specifically, the present invention relates to a system and a method calculating the electromagnetic energy consumption of components in a vehicle.

### BACKGROUND OF THE INVENTION

Electric vehicles are the transportation means of the future. Electric and hybrid cars and trains are already run in millions on roads all over the world, and electric airplanes and ships are under development. These vehicles include many electrotechnical and electrical components that emit electromagnetic (EM) emission. The EM emission includes a magnetic flux which depends on the current consumption of each electrical component, as shown for a simple wire component in equation (1):

$$\vert \vec{{B}_{J}} \vert = \vert \frac{{μ}_{0} \vec{ι}}{2 π r} \vert \qquad ( 1 )$$

Wherein, \vec{B} is the magnetic field vector generated by radiation component j (j=1 to M), i the current flowing in, to, or from an electric component and r the distance from the radiating component.

Electrotechnical and electrical components age and wear with time, this will require maintenances (e.g., fixing and/or replacement). Some traveling conditions, such as frequent accelerations and/or slopy terrane can accelerate the wearing of the electrotechnical and electrical components. These aging and wearing conditions can affect the EM emission and therefore the emitted magnetic flux, and the specific frequency, from the electrotechnical and electrical components.

Accordingly, the emitted and detected magnetic flux may be used for optimizing the energy/current consumption of a component in the vehicle and optionally also for detecting a maintenance problem in the vehicle.

### SUMMARY OF THE INVENTION

Some aspects of the invention may be related to a system and a method of calculating the current consumption of components in a vehicle. The system may include a controller and a memory stored thereon instructions for executing the method. In some embodiments, the method comprising: receiving from at least one magnetic flux sensor located at a known location in the vehicle, a magnetic flux pattern at various frequencies, indicative of the magnetic field at the location; identifying at least one first magnetic flux maximum at a first frequency corresponding to a first component of the vehicle; and calculating a first current consumption of the first component based on the at least one first magnetic flux maximum.

In some embodiments, the method may further include and changing at least one operational parameter of the vehicle based on the calculation.

In some embodiments, the method may further include generating a report comprising at least the first component, the first frequency, and the first current consumption. In some embodiments, the method may further include designing at least one parameter of the electric vehicle based on the generated report.

In some embodiments, the method further comprising: identifying at least one second magnetic flux maximum at a second frequency corresponding to a second component of the vehicle; and calculating a second current consumption of the second component based on the at least one second magnetic flux maximum In some embodiments, the method may further include changing at least one operational parameter of the vehicle and at least based on the second current consumption. In some embodiments, the method may further include generating a report comprising at least the second component, and the corresponding second frequency and second current consumption.

In some embodiments, identifying comprises identifying a first plurality of magnetic flux maxima and wherein calculating is based on at least two maxima. In some embodiments, identifying further comprises identifying at least one harmony among the first plurality of magnetic flux maxima.

In some embodiments, changing at least one operational parameter comprises, changing the electrical current provided to at least one of: the first component and the second component. In some embodiments, changing at least one operational parameter comprises, changing a driving profile of the car, wherein the driving profile is selected from, default, economy, and sport driving. In some embodiments, changing at least one operational parameter comprises activating the selected driving profile in a dynamic manner.

In some embodiments, changing at least one operational parameter comprises, changing the operation duration of at least one of: the first component and the second component. In some embodiments, changing at least one operational parameter comprises, changing an operation sequence of at least one of: the first component and the second component.

In some embodiments, calculating the current consumption is based on comparing the magnetic flux maximum to magnetic flux maxima stored in a database corresponding to current consumption of the first component. In some embodiments, calculating the current consumption includes calculating the current consumption based on at least one of: the magnetic flux value at the at least one first maximum, the width of the peak magnetic flux pattern associated with the at least one first maximum, the shape of the magnetic flux pattern associated with the at least one first minimum and the number of first magnetic flux maxima.

Some additional aspects of the invention may be directed to a method of identifying electric consumers in a vehicle, the method comprising: receiving from at least one magnetic flux sensor located at a known location in the vehicle, at least one magnetic flux pattern at various frequencies, indicative of the magnetic field at the location; and identifying at least one first magnetic flux maximum at a first frequency corresponding to a first component of the vehicle.

In some embodiments, the method may further include generating a report comprising at least the first component, and the corresponding first frequency; and sending the report to an external computing device. In some embodiments, the method may further include designing at least one parameter of the vehicle based on the generated report.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1A is a block diagram, depicting a system for optimizing the energy consumption of components in a vehicle according to some embodiments of the invention;

FIG. 1B is a block diagram, depicting a computing device which may be included in a system for optimizing the energy consumption of components in a vehicle according to some embodiments of the invention;

FIG. 2 is a flowchart of a method of calculating the energy consumption of components in a vehicle;

FIG. 3 is a graph showing three magnetic flux maxima detected at a known location in the vehicle according to some embodiments of the invention;

FIGS. 4A and 4B are graphs showing magnetic flux maxima detected near the rear engine and above the air-condition (AC) system of the vehicle according to some embodiments of the invention; and

FIG. 5 is a graph showing measurements of the total current consumption of some electrical components is a single vehicle during two different runs, in the same scenario, according to some embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention. Some features or elements described with respect to one embodiment may be combined with features or elements described with respect to other embodiments. For the sake of clarity, discussion of same or similar features or elements may not be repeated.

Although embodiments of the invention are not limited in this regard, discussions utilizing terms such as, for example, “processing,” “computing,” “calculating,” “determining,” “establishing”, “analyzing”, “checking”, “estimating”, “inferring”, or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium that may store instructions to perform operations and/or processes.

Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. The term set when used herein may include one or more items. Unless explicitly stated, the method embodiments described herein are not constrained to a particular order or sequence. Additionally, some of the described method embodiments or elements thereof can occur or be performed simultaneously, at the same point in time, or concurrently.

The term set when used herein can include one or more items. Unless explicitly stated, the method embodiments described herein are not constrained to a particular order or sequence. Additionally, some of the described method embodiments or elements thereof can occur or be performed simultaneously, at the same point in time, or concurrently.

Embodiments of the present invention disclose a method and a system for calculating the current consumption of components in a vehicle (e.g., an electric vehicle). The calculated current consumption may be used for optimizing the energy consumption of the vehicle. Additionally, or alternatively, the calculated current consumption may be collected and provided as a report, for example, for vehicle manufacturers in order to improve the design of at least one component of the vehicle.

The method may include placing one or more magnetic flux sensors at one or more known locations in the vehicle. The magnetic flux sensors may measure the mantic flux (e.g., in micro-Tesla, milligauss, etc.) at various frequencies. The inventors have surprisingly found that each electrical component in the vehicle emits magnetic flux having maximum flux at a typical frequency or band of frequencies. These typical frequencies may allow identifying the emission from two or more different components in a single mantic flux pattern, measured at a single location.

In some embodiments, the maximum flux may be indicative or proportional to the current consumption of the component, for example, as shown for a simple wire component in equation (1). Accordingly, measuring the magnetic flux pattern at various frequencies, using, a single sensor can be indicative of the current and therefore the energy consumption of the vehicle's components. The current consumption of each component may be compared to an optimized or previously-stored current consumption in order to check if the component works at optimal conditions. If not, then at least one operational parameter of the component can be changed, as discussed herein below.

The electrical, electronic, and electromechanical components of the vehicle may include, for example, the vehicle's electric motors, the vehicle's air-conditioning (AC) system, the vehicle seat heaters, the vehicle's electric wires, the vehicle computer, the vehicle's power inverters, the vehicle's relay switches, the vehicle's radiofrequency (RF) components, autonomous vehicle's processor, and the like.

As used herein, a “vehicle” may be any form of transportation that includes one or more EM radiating components. For example, a vehicle may be, an internal combustion engine (ICE) powered vehicle, an electric car, a hydrogen-powered vehicle, a hybrid car, an electric bus, an electric train, an electric ship, an electric airplane, an electric drone, an electric bike, an electric motorbike, an electric scooter, a maglev train, an elevator, a moving stairway, a roller conveyor, a treadmill, and the like. A “vehicle” may alternatively be any form of enclosure a human may be in, including for fitness or medical reasons. For example, an MRI scanner.

As used herein, a frequency may refer to the entire EM frequency spectrum. More specifically, the frequency spectrum may be defined according to the IEC standard 62764-1, for example, 1 Hz-400 Kz which were found to be the frequency band at which most of the electrical components of the vehicle emit magnetic flux.

As used herein, a “component” may be any component of the vehicle that radiates EM emission (at any spectrum). Some examples, so for radiating components radiating EM emission at the ELF may include: the vehicle's electric motors, the vehicle's electric wires, at least one of the vehicle's computers (e.g., an HPC architecture of electrical vehicles), the vehicle's power inverters, the vehicle's relay switches and the like.

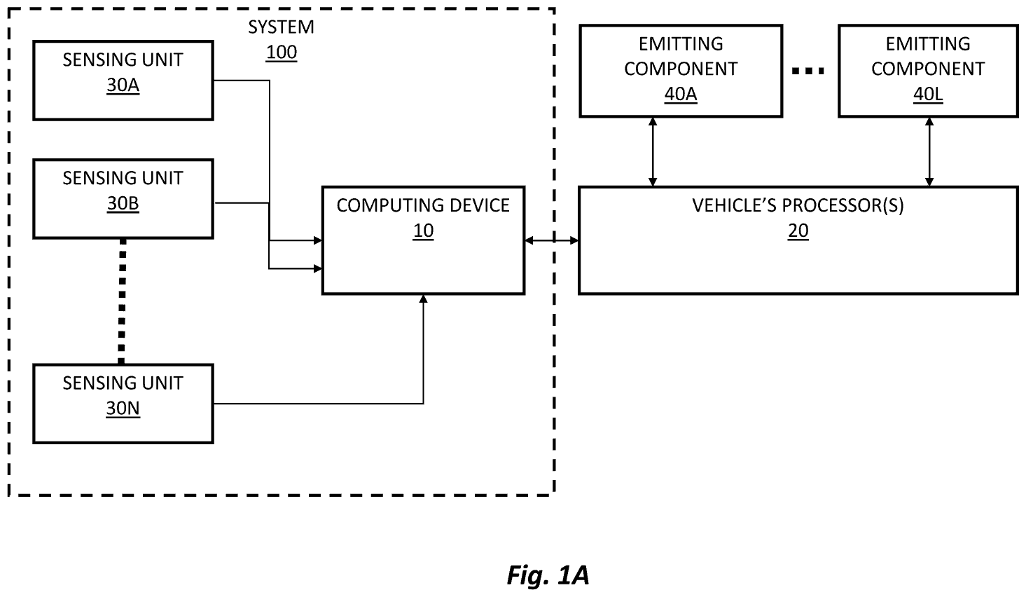

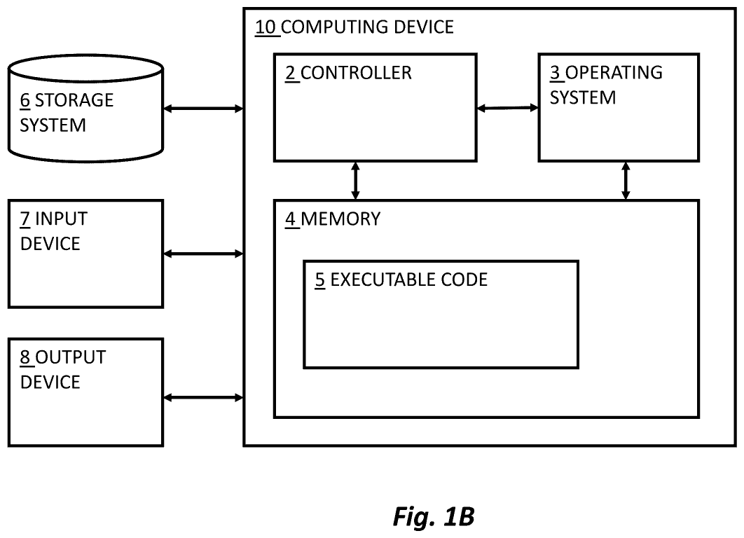

Reference is now made to FIG. 1A, which is a block diagram of a system for analyzing the current consumption of components in a vehicle (e.g., an electric vehicle) according to some embodiments of the invention. A system such as a system 100 may include a computing device 10, illustrated and discussed in FIG. 1B, that may be in communication with one or more of the vehicle's processors 20, for example, via I/O devices 7 and 8. In some embodiments, system 100 may include or may be in communication with one or more sensors 30A-30N. As should be understood by one skilled in the art the three sensors illustrated in FIG. 1A are given as an example only and any number of EM sensors can be included in the invention. In some embodiments, EM sensors 30A-30N may communicate with computing device 10 via either wired and/or wireless communication using any known protocol (e.g., LAN, Bluetooth, and the like).

In some embodiments, sensors 30A-30N may include any sensor configured to detect an emission vector of magnetic flux density generated by a component of the vehicle. In some embodiments, units 30A-30N may each include a single magnetic flux sensor configured to measure a magnetic flux pattern at various frequencies. For example, the sensors may be, NARDA EHP-50F, Anisotropic Magneto-resistive (AMR) sensors, such as Honeywell HMC104, available from Honeywell, Hall Effect sensors, such as DRV5053 available from Texas, Instruments, and the like. In a non-limiting example, the sensor may be a magnetic field sensor that includes a 3 axis coil sensor and a computing system. In some embodiments, units 30A-30N may measure magnetic flux patterns at micro-Tesla or milligauss. In some embodiments, other sensors may be included or communicate with system 100, for example, Wireless Power Transfer (WPT) for smartphone charging, speakers, or other vehicle sensors with signal processing capabilities.

In some embodiments, one or more sensors 30A-30N may be assembled at a reference location in the vehicle, for example, near the driver's wheel, below the driver's chair, and the like.

In some embodiments, one or more sensors 30A-30N may be assembled at the closest assembling location to each radiating component. For example, a sensor 30A may be assembled on the envelope of the vehicle's electric motors (e.g., rear motor and/or front motor). In another example, a sensor 30B may be attached to a wire of the vehicle. In yet another example, a sensor 30C may be attached to the AC system of the vehicle.

In some embodiments, the vehicle may include a plurality of vehicle processors 20, and system 100 may communicate with at least one vehicle processor 20, which may be a computing device, such as computing device 10.

In some embodiments, components 40A-40L may be any component of the vehicle that radiates EM emission (at any spectrum). Some examples of radiating components generating magnetic flux may include the vehicle's electric motor(s), the vehicle's electric wires, at least one of the vehicle's computers 20, the vehicle's power inverters, the vehicle's relay switches, the vehicle's air condition system, chair heating system, and the like.

Reference is now made to FIG. 1B, which is a block diagram depicting a computing device, which may be included within a system for calculating the current consumption of components in a vehicle (e.g., an electric vehicle), according to some embodiments. A computing device, such as device 10 may be included in the vehicle's computing system. In some embodiments, more than one computing device 10 may be included in the vehicle's computing system.

Computing device 10 may include a controller 2 that may be, for example, a central processing unit (CPU) processor, a chip or any suitable computing or computational device, an operating system 3, a memory 4, executable code 5, a storage system 6, input devices 7 and output devices 8. Controller 2 (or one or more controllers or processors, possibly across multiple units or devices) may be configured to carry out methods described herein, and/or to execute or act as the various modules, units, etc. More than one computing device 10 may be included in, and one or more computing devices 10 may act as the components of, a system according to embodiments of the invention.

Operating system 3 may be or may include any code segment (e.g., one similar to executable code 5 described herein) designed and/or configured to perform tasks involving coordination, scheduling, arbitration, supervising, controlling, or otherwise managing the operation of computing device 10, for example, scheduling execution of software programs or tasks or enabling software programs or other modules or units to communicate. Operating system 3 may be a commercial operating system. It will be noted that an operating system 3 may be an optional component, e.g., in some embodiments, a system may include a computing device that does not require or include an operating system 3.

Memory 4 may be or may include, for example, a Random Access Memory (RAM), a read-only memory (ROM), a Dynamic RAM (DRAM), a Synchronous DRAM (SD-RAM), a double data rate (DDR) memory chip, a Flash memory, a volatile memory, a non-volatile memory, a cache memory, a buffer, a short term memory unit, a long term memory unit, or other suitable memory units or storage units. Memory 4 may be or may include a plurality of, possibly different memory units. Memory 4 may be a computer or processor non-transitory readable medium, or a computer non-transitory storage medium, e.g., a RAM. In one embodiment, a non-transitory storage medium such as memory 4, a hard disk drive, a solid-state disk, a flash memory, another storage device, etc. may store instructions or code which when executed by a processor may cause the processor to carry out methods as described herein.

Executable code 5 may be any executable code, e.g., an application, a program, a process, task, or script. Executable code 5 may be executed by controller 2 possibly under the control of operating system 3. For example, executable code 5 may be an application that may detect a maintenance problem in a vehicle as further described herein. Although, for the sake of clarity, a single item of executable code 5 is shown in FIG. 1B, a system according to some embodiments of the invention may include a plurality of executable code segments similar to executable code 5 that may be loaded into memory 4 and cause controller 2 to carry out methods described herein.

Storage system 6 may be or may include, for example, a flash memory as known in the art, a memory that is internal to, or embedded in, a microcontroller or chip as known in the art, a hard disk drive, a CD-Recordable (CD-R) drive, a Blu-ray disk (BD), a universal serial bus (USB) device or other suitable removable and/or fixed storage unit. For example, parameters of the vehicle, (virtual) meshing of the vehicle, the location of EM sensors, and/or the locations of radiating components may be stored in storage system 6 and may be loaded from storage system 6 into memory 4 where it may be processed by controller 2. In some embodiments, some of the components shown in FIG. 1B may be omitted. For example, memory 4 may be a non-volatile memory having the storage capacity of storage system 6. Accordingly, although shown as a separate component, storage system 6 may be embedded or included in memory 4. In some embodiments, storage system 6 may be a cloud base storage system.

Input devices 7 may be or may include any suitable input devices, components, or systems, e.g., a detachable keyboard or keypad, a mouse, and the like. Output devices 8 may include one or more (possibly detachable) displays or monitors, speakers, and/or any other suitable output devices. Any applicable input/output (I/O) devices may be connected to Computing device 10 as shown by blocks 7 and 8. For example, a wired or wireless network interface card (NIC), a universal serial bus (USB) device, or an external hard drive may be included in input devices 7 and/or output devices 8. It will be recognized that any suitable number of input devices 7 and output device 8 may be operatively connected to Computing device 1 as shown by blocks 7 and 8.

A system according to some embodiments of the invention may include components such as, but not limited to, a plurality of central processing units (CPU) or any other suitable multi-purpose or specific processors or controllers (e.g., controllers similar to controller 2), a plurality of input units, a plurality of output units, a plurality of memory units, and a plurality of storage units.

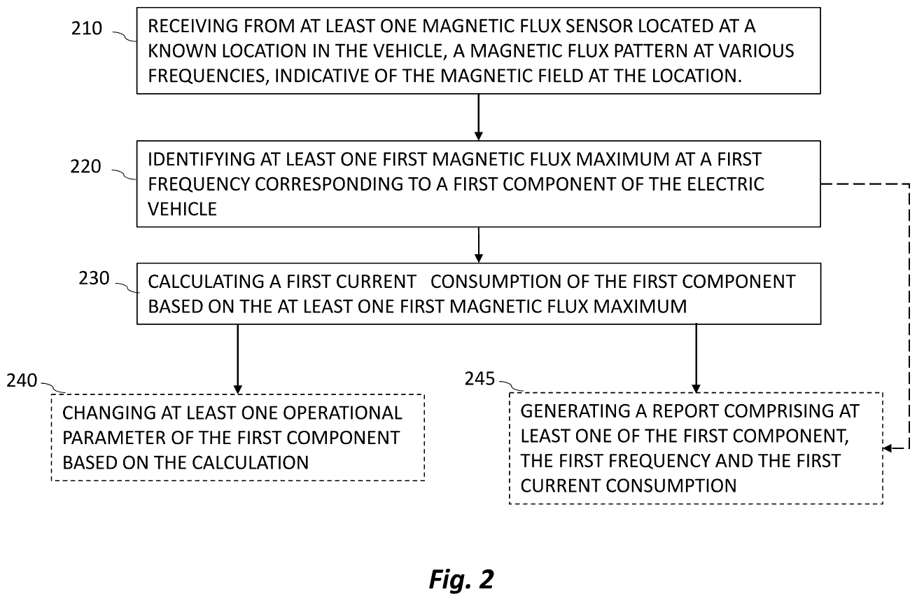

Reference is now made to FIG. 2 which is a flowchart of a method of calculating the current consumption of components in a vehicle (e.g., an electric vehicle) according to some embodiments of the invention. The method of FIG. 2 may be performed by computing device 10 or any other processor or controller.

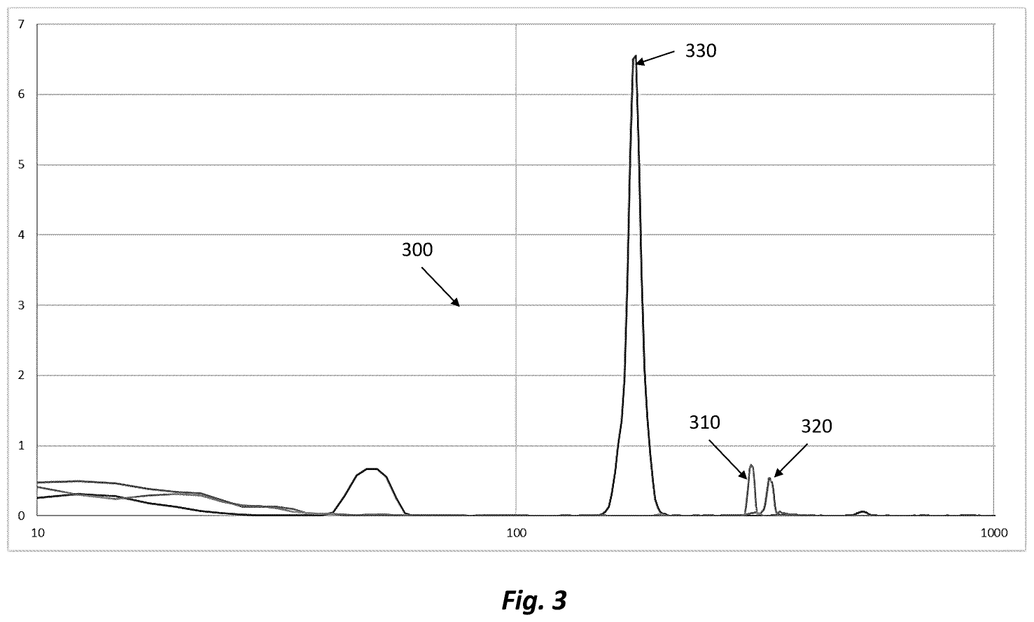

In step 210, at least one magnetic flux pattern at various frequencies, indicative of the magnetic field at a location in the vehicle may be received from at least one magnetic flux sensor (e.g., sensor 30A) located at a known location in the vehicle. Computing device 10 may receive at least one magnetic flux pattern in a range of 1 Hz to 400 KHz, for example, pattern 300, given in the graph in FIG. 3. In the non-limiting example of FIG. 3, the Y-axis is the size of the magnetic flux in micro-Tesla and the X-axis is the frequency in Hz. The pattern was measured by a sensor (e.g., NARDA EHP-50F or the like) placed at the elbow between the driver and the front passenger.

In step 220, at least one first magnetic flux maximum may be identified at a first frequency corresponding to a first component of the vehicle. In some embodiments, at least one second magnetic flux maximum may be identified at a second frequency corresponding to a second component of the vehicle For example, maximum 310 at 310 Hz was identified as corresponding to the magnetic flux of the rear engine, maximum 320 at 340 Hz was identified as corresponding to the magnetic flux of the front engine and maximum 330 at 170 Hz was identified as corresponding to the magnetic flux of the air-condition system working in cooling mode.

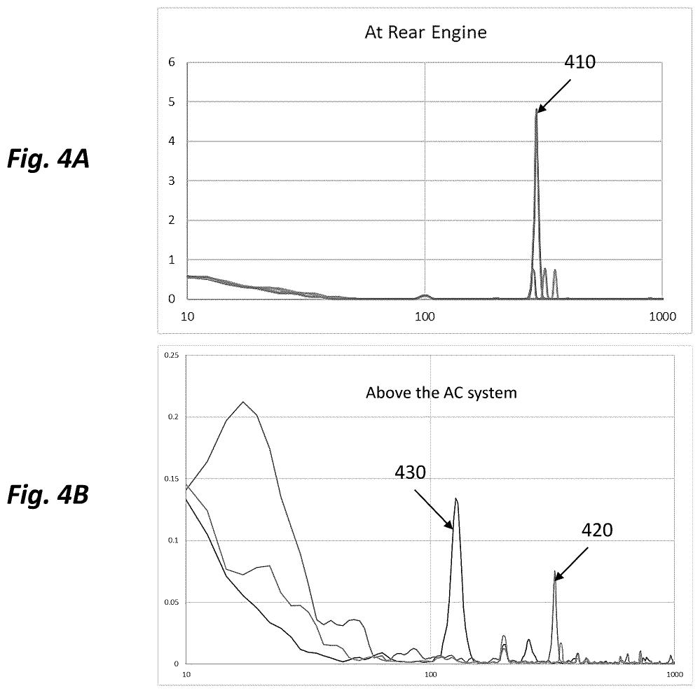

In some embodiments, a learning stage may be conducted in order to find the typical frequencies of various components. In some embodiments, more than one frequency or a band of frequencies may be found, as the maximum may shift with time or under different operational parameters. The learning stage may include placing a sensor (e.g., sensor 30B) in proximity to a first component, such that the highest maximum received is from the first component. Two non-limiting examples for such learning stages are shown in the graphs of FIGS. 4A and 4B.

FIG. 4A is a graph showing the magnetic flux pattern measured in proximity to the rear engine. The highest maximum 410 in around 300 Hz and the short maxima are harmonies of the magnetic flux pattern of the rear engine. Similar measurements were conducted for the front engine that showed similar behavior, shifted to the right in comparison to the rear engine.

FIG. 4B is a graph showing the magnetic flux pattern measured in proximity to the AC system. The AC system in this specific car is located in a short distance from the front engine accordingly two major maxima were measured 420 at 320 Hz, related to the front engine, and 430 at 155 Hz related to the AC system.

Accordingly, computer device 10 may look for data stored in storage system 6 for correlations between detected maxima frequencies and the current consumption of various components of the vehicle, at different driving scenarios and operation state.

A nonlimiting example for a lookup table acquired, using system 100, assembled at a specific car at the premises of a car manufacturer is given in table 1. The data of table 1 was collected when all batteries of the vehicle were 100% charged. All the measurements taken in table 1, were conducted using the Worldwide Harmonised Light Vehicle Test Procedure (WLTP). The WLPT measures the range of a car travelling at an average speed of 30 mph in summer temperatures from a 100% to 0% state of charge.

The different driving scenarios that were tested included, 1) engine off, 2) and power on during parking, 3) power on during driving.

As shown in table 1, a component may have different maxima at different frequencies during different driving scenarios and/or different operation states. For example, when the power is on during parking, the air conditioning (AC) system has maximum at 720 Hz during maximum cooling and 775 Hz during maximum heating. When the vehicle is driving the AC system has maximum at 757 Hz during maximum cooling and 790 Hz during maximum heating.

TABLE 1

| | Vehicle Component | |
|---|---|---|
| Driving scenario | and state | Frequency |
| Power Off- engine Off | default | car is locked |
| Power On - Parking | none (defaults are on) | 200 Hz with harmony - |
| | | internal lights |
| | | 512 Hz - passenger seat |
| | | light |
| | Brakes pedal | 110 Hz with harmony |
| | AC max COLD | AC Cold - 720 Hz |
| | AC max HOT | AC HOT - 775 Hz |
| | Windows down | 144 Hz |
| | Windows up | 124 Hz |
| | Auto driving lights | 125 Hz |
| Power On - Driving | none (defaults are on) | pedal brakes / brakes |
| | | lights are ON |
| | Brakes pedal | 110 Hz with harmony |
| | AC max COLD | 757 Hz |
| | AC max HOT | 790 Hz |
| | Windows down | 144 Hz |
| | Windows up | 124 Hz |
| | Auto driving lights | 125 Hz |

In some embodiments, some of the components may have several harmonic maxima (e.g., the braking pedal).

In some embodiments, the list of all the components identified as working in step 220 may be generated and sent to an external computing device, for example, a computing device associated with the vehicle manufacturer. The list may assist the vehicle manufacturer to identify hidden energy consumers, that are not indicated as energy consumers by the vehicle's computing system.

For example, currently the vehicle manufacturer can receive the list of current consumers from the vehicle's network. The method according to embodiments of the invention may identify all the EM emitting components, even if not indicated by the vehicle's network as consuming current/energy. Therefore, a system and method according to embodiments of the invention may assist in manufacturing vehicles having lower energy/current consumption, as the method allows to identify hidden energy consumers.

In step 230, the current consumption of the first component may be calculated based on the at least one first magnetic flux maximum. For example, current consumption may be calculated from equation (1), or similar equanimous, when the distance r from sensor 30A to component 40A is known. In another example, computing device 10 may look at a lookup table stored in storage system 6 for correlations between the height of the maxima and the current consumption. Therefore, calculating the current consumption is based on comparing the magnetic flux maximum to magnetic flux maxima stored in a database corresponding to current consumption of the first component.

In some embodiments, calculating the current consumption includes calculating the current consumption based on at least one of: the magnetic flux value at the at least one first maximum, the width of the peak magnetic flux pattern associated with the at least one first maximum, the shape of the magnetic flux pattern associated with the at least one first minimum and the number of first magnetic flux maxima.

In some embodiments, the same type of calculations may be performed to the second component (e.g., component 40B) or to any other component in the vehicle.

In some embodiments, a first calculated current consumption associated with the first component may be utilized in various ways.

In some embodiments, computing device 10 may collect, associate and store in storage system 6, various magnetic flux patterns associated with various driving profiles, user preferences, driving conditions, and the like. In some embodiments, for all stored magnetic flux patterns at least one magnetic flux maximum was identified at a first frequency corresponding to a component of the vehicle, and the current consumption of the component was calculated.

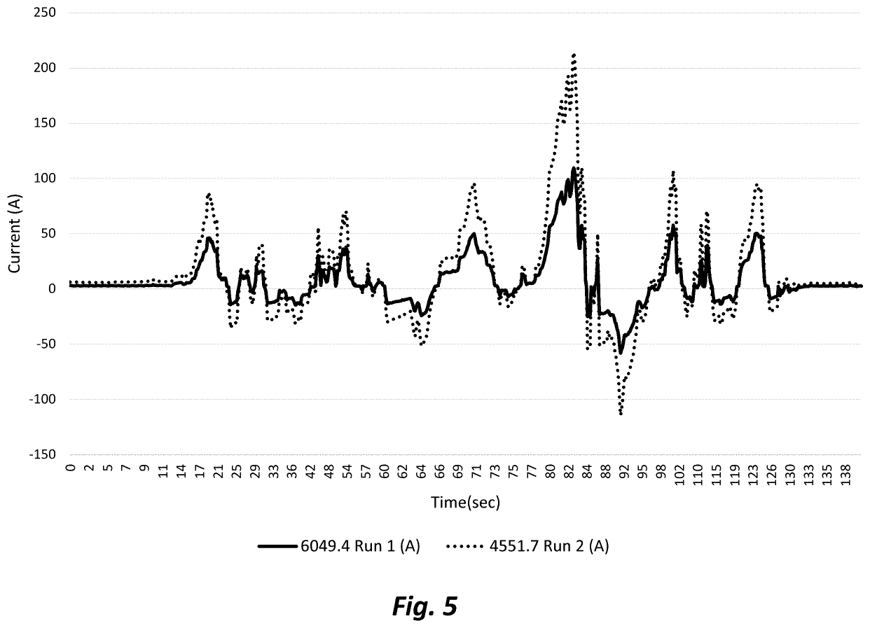

Reference is now made to FIG. 5 which is a graph showing measurements of the total current consumption of some electrical components in a single vehicle during two different runs, in the same scenario, according to some embodiments of the invention. In the nonlimiting example, shown in FIG. 5, the total current consumed in 140 seconds was 6049.4 Amp while the in the second run 4551.7 Amp. During the experiment the same vehicle was run twice in the same lab environment, under the same scenario, during the same time, under the same environmental conditions (e.g., temperature, humidity, wind, precipitations, etc.), therefore, there was no external reason for difference in the current consumption. The difference in current consumption can be due to the fact that some electric components may be active and consume power but vehicle's network messages system does not reflect it and therefore the “same scenario” consumes two different currents. The frequency/magnetic fields data, measured according to embodiments of the invention, on the other hand, reflects exactly which component is active, and in some cases, its level of energy consumption. For example, in step 240, at least one operational parameter of the vehicle may be changed based on the calculation. In some embodiments, at least one operational parameter of the vehicle may also be changed based on the calculation. In some embodiments, changing at least one operational parameter comprises, changing the current provided to at least one of: the first component and the second component.

In some embodiments, changing at least one operational parameter comprises, changing a driving profile of the car, wherein the driving profile is selected from, default, economy, and sport driving. In some embodiments, changing at least one operational parameter comprises activating the selected driving profile in a dynamic manner, for example, the sport profile may be modified based on the current consumption of the rear and/or front engines such that the current consumption is limited in some portions of the way, for example, during uphill claiming, in order to save energy.

In some embodiments, changing at least one operational parameter comprises, changing the operation duration of at least one of: the first component and the second component. For example, an automatic shutting down of the air-conditioning system may be performed after 30 minutes. In some embodiments, changing at least one operational parameter comprises, changing an operation sequence of at least one of: the first component and the second component. For example, seat heating may be limited to operating no more than 2 minutes every 5 minutes.

In yet another example, in step 245 a report may be generated comprising at least the first component, the first frequency, and the first current consumption. In some embodiments, the report may be sent to an external computing device associated with the vehicle manufacturer. In some embodiments, at least one parameter of the vehicle may be designed/redesigned based on the generated report. For example, the vehicle manufacturer may replace the component, calibrate the component, reprogram the component, and the like. In some embodiments, detecting and identifying the frequency of a magnetic flux maximum associated with a component can be indicative to the state of the component. More specifically, a shift in the maximum location to a different frequency may be indicative of a maintenance problem. For example, if the maximum in the magnetic flux associated with the AC system is found to be at 100 Hz instead of between 150-180 Hz, this shift may be indicative that the AC requires maintenance. Therefore, computing device 10 may compare the frequency maximum for various components to the frequencies stored in storage system 6 and if a deviation (e.g., shift) larger than a threshold value is detected, computing device 10 may send an alert that the component requires inspection.

Some nonlimiting examples for using the system and methods according to some embodiments of the invention may include adjustment of components in a hydrogen vehicle. In some embodiments, the efficiency of the electricity production is a function of the momentary current consumption and the configuration of hydrogen fuel cell. Accordingly, the real-time efficiency may be optimized if the current consumption is known. Furthermore, the future efficiency can be optimized if the outlook consumption is known. The method according to some embodiments of the invention may assist in predicting, based on the ability to identify and monitor different the fuel cell and various consumers in the hydrogen vehicle a futuristic behavior, for example, based on similar driving scenarios. In some embodiments, the outcome may lead to either adjusting the hydrogen fuel cell (since the gradient of energy consumption can be investigated) or adjusting the operational parameters of the consumers.

Another nonlimiting example may include “trend analysis” which includes mapping the consumption of some or all consumers over time. Therefore, even if the effective overall current consumption has not been changed (superposition), individual consumers might change over the lifetime of the vehicle (e.g., due to aging), such a mapping may allow identifying the aging component. In the case that the superposition shows effective drift e.g., consumption increases, such method may again allow to identify the aging/drifting component. In some embodiments, the method may help to categorize and identify the root cause, this could also help to reduce failures in the car (which consumer causes the problem).

The system and methods according to some embodiments of the invention may be used and the vehicle manufacturer premises, at a service station, dealership, and/or during the entire lifetime of the vehicle.

Unless explicitly stated, the method embodiments described herein are not constrained to a particular order or sequence. Furthermore, all formulas described herein are intended as examples only and other or different formulas may be used. Additionally, some of the described method embodiments or elements thereof may occur or be performed at the same point in time.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

Various embodiments have been presented. Each of these embodiments may of course include features from other embodiments presented, and embodiments not specifically described may include various features described herein.

1. A method of calculating the current consumption of components in a vehicle, the method comprising:
receiving from at least one magnetic flux sensor located at a known location in the vehicle, at least one magnetic flux pattern at various frequencies, indicative of the magnetic field at the location;
identifying at least one first magnetic flux maximum at a first frequency corresponding to a first component of the vehicle;
calculating a first current consumption of the first component based on the at least one first magnetic flux maximum;
changing at least one operational parameter of the vehicle based on the calculation.

2. (canceled)

3. The method of claim 1, further comprising:
generating a report comprising at least the first component, and the corresponding first frequency and the first current consumption.

4. The method of claim 3, further comprising:
designing at least one parameter of the vehicle based on the generated report.

5. The method of claim 1, further comprising:
identifying at least one second magnetic flux maximum at a second frequency corresponding to a second component of the vehicle; and
calculating a second current consumption of the second component based on the at least one second magnetic flux maximum.

6. The method of claim 5, further comprising
changing at least one operational parameter of the vehicle based on the calculation.

7. The method of claim 5, further comprising:
generating a report comprising at least the second component, and the corresponding second frequency and second current consumption.

8. The method of claim 1, wherein
identifying comprises identifying a first plurality of magnetic flux maxima and wherein calculating is based on at least two maxima.

9. The method of claim 8, wherein identifying further comprises identifying at least one harmony among the first plurality of magnetic flux maxima.

10. The method of claim 1, wherein changing at least one operational parameter comprises, changing the electrical current provided to at least one of: the first component and the second component.

11. The method of claim 1, wherein changing at least one operational parameter comprises, changing a driving profile of the car, wherein the driving profile is selected from, default, economy, and sport driving.

12. The method of claim 11, wherein changing at least one operational parameter comprises activating the selected driving profile in a dynamic manner.

13. The method according to claim 6, wherein changing at least one operational parameter comprises, changing the operation duration of at least one of: the first component and the second component.

14. The method according to claim 6, wherein changing at least one operational parameter comprises, changing an operation sequence of at least one of: the first component and the second component.

15. The method of claim 1, wherein calculating the current consumption is based on comparing the magnetic flux maximum to magnetic flux maxima stored in a database corresponding to current consumption of the first component.

16. The method of claim 1, wherein calculating the current consumption includes calculating the current consumption based on at least one of: the magnetic flux value at the at least one first maximum, the width of the peak magnetic flux pattern associated with the at least one first maximum, the shape of the magnetic flux pattern associated with the at least one first minimum and the number of first magnetic flux maxima.

17. A system for calculating the current consumption of components in a vehicle, the method comprising:
a processor; and
a memory sorted thereon instructions to be executed by the processor, the instructions comprise:
receiving from at least one magnetic flux sensor located at a known location in the vehicle, a magnetic flux pattern at various frequencies, indicative of the magnetic field at the location;
identifying at least one first magnetic flux maximum at a first frequency corresponding to a first component of the vehicle;
calculating a first current consumption of the first component based on the at least one first magnetic flux maximum; and
changing at least one operational parameter of the vehicle based on the calculation.

18. (canceled)

19. The system of claim 17, wherein the instructions further comprise:
generating a report comprising at least the first component, and the corresponding first frequency and the first current consumption.

20. The system of claim 19, wherein the instructions further comprise:
designing at least one parameter of the vehicle based on the generated report.

21. The system of claim 17,
wherein the instructions further comprise:
identifying at least one second magnetic flux maximum at a second frequency corresponding to a second component of the vehicle;
calculating a second current consumption of the second component based on the at least one second magnetic flux maximum; and
changing at least one operational parameter of the vehicle and at least based on the calculation.

22.-35. (canceled)
